(19) United States
(12) Patent Application Publication
(10) Pub. No.: US 2022/0037558 A1
(43) Pub. Date: Feb. 3, 2022

(54) OPTOELECTRONIC SEMICONDUCTOR CHIP AND METHOD FOR PRODUCING AN OPTOELECTRONIC SEMICONDUCTOR CHIP

(71) Applicant: Osram OLED GmbH, Regensburg (DE)

(72) Inventor: Siegfried HERRMANN, Neukirchen (DE)

(21) Appl. No.: 17/276,492

(22) PCT Filed: Sep. 16, 2019
(86) PCT No.: PCT/EP2019/074685

§ 371 Date: Mar. 16, 2021

(30) Foreign Application Priority Data
Sep. 17, 2018 (DE) 10 2018 122 684.5

(51) Int. Cl. H01L 33/24; H01L 31/18; H01L 33/00; H01L 31/0352

(52) U.S. Cl. CPC H01L 33/24; H01L 31/0352; H01L 33/0093; H01L 31/1892

(57) ABSTRACT

An optoelectronic semiconductor chip comprises a semiconductor layer sequence and several semiconductor structures having in each case one active region. The active regions may be designed for the emission and/or absorption of electromagnetic radiation. The active regions of different semiconductor structures may not be connected to one another. The semiconductor structures may be designed as a nanorod or a microrod. The semiconductor structures may be embedded in the semiconductor layer sequence.

### CROSS-REFERENCE TO RELATED APPLICATIONS

The present application is a national stage entry according to 35 U.S.C. § 371 of PCT Application No. PCT/EP2019/074685 filed on Sep. 16, 2019; which claims priority to German Patent Application Serial Nos. 10 2018 122 684.5 filed on Sep. 17, 2018; all of which are incorporated herein by reference in their entirety and for all purposes.

### TECHNICAL FIELD

An optoelectronic semiconductor chip is specified. Furthermore, a method for producing an optoelectronic semiconductor chip is specified.

### BACKGROUND

One problem to be solved is to provide a particularly efficient optoelectronic semiconductor chip. Another problem to be solved is to specify a method for producing such an optoelectronic semiconductor chip.

### SUMMARY

First, an optoelectronic semiconductor chip is specified. The semiconductor chip can be used, for example, in light-emitting diodes or SSL or SMT devices or as a laser diode chip. For example, the semiconductor chip is suitable for use in video screens or in headlights, especially front headlights, for vehicles. Furthermore, the semiconductor chip is suitable for sensors, such as 3D sensors.

According to at least one embodiment of the optoelectronic semiconductor chip, the latter comprises a semiconductor layer sequence. The semiconductor layer sequence is connected, in particular simply connected.

For example, the semiconductor layer sequence is based on a III-V compound semiconductor material. The semiconductor material is, for example, a nitride compound semiconductor material, such as AlₙIn₁₋ₙ₋ₘGaₘN, or a phosphide compound semiconductor material, such as AlₙIn₁₋ₙ₋ₘGaₘP, or an arsenide compound semiconductor material, such as AlₙIn₁₋ₙ₋ₘGaₘAs or AlₙIn₁₋ₙ₋ₘGaₘAsP, where 0≤n≤1, 0≤m≤1, and m+n≤1, respectively. In this context, the semiconductor layer sequence may have dopants as well as additional components. For simplicity, however, only the essential components of the crystal lattice of the semiconductor layer sequence, i.e. Al, As, Ga, In, N or P, are indicated, even though these may be partially replaced and/or supplemented by small amounts of additional substances. In a non-limiting embodiment, the semiconductor layer sequence is based on AlInGaN.

A lateral extension of the semiconductor chip, measured along the main extension plane of the semiconductor layer sequence, is, for example, at most 5% or at most 10% larger than the lateral extension of the semiconductor layer sequence.

According to at least one embodiment, the optoelectronic semiconductor chip comprises a plurality of semiconductor structures each having an active region. The active regions comprise in particular in each case at least one pn junction and/or at least one quantum well structure in the form of a single quantum well, in short SQW, or in the form of a multi quantum well structure, in short MQW. In addition to the active region, the semiconductor structures comprise two semiconductor sections each, between which the active region is arranged. The semiconductor sections on different sides of the active region can be doped differently.

The active region of the semiconductor structures is, for example, shaped three-dimensionally in each case. An interface between the active region and an adjacent semiconductor section is, for example, not continuously flat, but is, for example, curved or has edges. The interface has, for example, the shape of the lateral surface of a cone or a truncated cone or a pyramid or a truncated pyramid.

The semiconductor material of the semiconductor structures may be based on the same III-V compound semiconductor material as the semiconductor layer sequence. Only the exact stoichiometric composition of the semiconductor structures then differs, for example, from that of the semiconductor layer sequence.

According to at least one embodiment, the active regions are each configured for emission and/or absorption of electromagnetic radiation. In particular, the active regions are configured for emission and/or absorption in the visible spectral range or in the near UV range or in the near infrared range. For example, the active regions are configured for emission and/or absorption of electromagnetic radiation in a range between 350 nm and 850 nm inclusive.

According to at least one embodiment, the active regions of different semiconductor structures are not connected. That is, the active regions of different semiconductor structures are separated and spaced apart from each other. In a non-limiting embodiment, the semiconductor structures are also not connected to each other, but are separated and spaced apart from each other. For example, the semiconductor structures or a subset of the semiconductor structures may be arranged adjacent to each other in a plane parallel to a main extension plane of the semiconductor layer sequence. For example, the semiconductor structures are arranged regularly or irregularly along this plane.

According to at least one embodiment, the semiconductor structures are each formed as a nanorod or as a microrod, in German “Nanostab” or “Mikrostab”. Thus, the semiconductor structures are elongated structures with an aspect ratio of at least 1 or at least 1.3 or at least 2, where the aspect ratio is defined as the ratio of length to diameter. For example, the aspect ratio is at most 10 or at most 5. Nanorods have a diameter of, for example, at least 10 nm and at most 1 μm. Microrods have a diameter of, for example, more than 1 μm and, for example, at most 10 μm. The nanorods or microrods may each have, for example, the shape of a quadrangular or hexagonal obelisk or pyramid or cone or cylinder. Longitudinal axes of the semiconductor structures all run parallel to each other, for example, within the manufacturing tolerance. The longitudinal axes of the semiconductor structures run perpendicular to the main extension plane of the semiconductor layer sequence within the manufacturing tolerance.

In particular, the nanorods or microrods can be formed in a core-shell structure. That is, a semiconductor section forms a core that is at least partially encased by the active region. The active region is in turn encased by a further semiconductor section in the form of a layer.

According to at least one embodiment, the semiconductor structures are embedded or buried in the semiconductor layer sequence. In particular, the semiconductor structures are epitaxially overgrown with the semiconductor layer sequence. For example, the semiconductor structures are completely surrounded by the semiconductor layer sequence in all lateral directions, parallel to the main extension plane of the semiconductor layer sequence, or in all spatial directions.

In at least one embodiment, the optoelectronic semiconductor chip comprises a semiconductor layer sequence and a plurality of semiconductor structures each having an active region. The active regions are each configured to emit and/or absorb electromagnetic radiation. The active regions of different semiconductor structures are not connected. The semiconductor structures are each formed as a nanorod or a microrod. The semiconductor structures are embedded in the semiconductor layer sequence.

In particular, the active or passive semiconductor structures may be buried in a semiconductor layer sequence. As passive structures, the semiconductor structures may be, for example, conversion elements. As active structures, the semiconductor structures are configured for intrinsic generation of electromagnetic radiation and can, for example, form different pixels of a semiconductor chip. By embedding the semiconductor structures in the semiconductor layer sequence, a final encapsulation layer for the semiconductor structures is not necessary. Embedding the semiconductor structures is also advantageous for the thermal properties.

By adjusting the density of the semiconductor structures, the intensity or chromaticity coordinate of the semiconductor chip can be adjusted. In addition, the semiconductor structures can be overgrown with the semiconductor layer sequence. When the semiconductor layer sequence grows, the semiconductor structures have a positive effect in terms of reducing lattice defects. For example, the semiconductor structures can act like a PSS (Patterned Sapphire Substrate). By adjusting the diameters of the semiconductor structures, the wavelength of the radiation emitted or absorbed by the semiconductor structures can be adjusted. Details of this can be found, for example, in the paper “Full-Color Single Nanowire Pixels for Projection Displays” Yong-Ho Ra et al, Nano Lett, 2016, 16 (7), pp 4608-4615, the disclosure content of which is hereby incorporated by reference.

According to at least one embodiment, the semiconductor structures are conversion elements. In this case, the semiconductor structures are thus passive elements.

According to at least one embodiment, the semiconductor layer sequence comprises an active layer that generates or absorbs primary radiation during intended operation. The active layer of the semiconductor layer sequence includes in particular at least one pn junction and/or at least one quantum well structure in the form of a single quantum well, abbreviated as SQW, or in the form of a multi quantum well structure, abbreviated as MQW. The active layer may generate or absorb electromagnetic radiation in the blue or green or red spectral region or in the UV region or in the IR region during intended operation. The active layer of the semiconductor layer sequence can be formed continuously. For example, a lateral extent of the active layer is at least 95% of the lateral extent of the semiconductor layer sequence.

According to at least one embodiment, the conversion elements are configured to convert the primary radiation into a secondary radiation or to convert a secondary radiation into the primary radiation. The primary radiation and the secondary radiation comprise different wavelength ranges. For this purpose, the semiconductor structures absorb the primary radiation. By a recombination of the electron-hole pairs resulting from the absorption in the active region, the secondary radiation is emitted.

According to at least one embodiment, the semiconductor structures are epitaxially overgrown with the semiconductor layer sequence. This is not only a process feature, but also a physical feature which can be verified on the finished semiconductor chip. In particular, no bonding material, such as an adhesive, is arranged between the semiconductor structures and the semiconductor layer sequence in this case, but the two components are directly adjacent to each other.

According to at least one embodiment, the semiconductor structures are arranged between the active layer and a growth substrate of the semiconductor layer sequence. The semiconductor layer sequence is grown on the growth substrate. The growth substrate is part of the semiconductor chip. The growth substrate may be sapphire. For example, the semiconductor chip is then a so-called sapphire chip or a flip chip.

According to at least one embodiment, the semiconductor chip is free of a growth substrate of the semiconductor layer sequence. Thus, after growing the semiconductor layer sequence on a growth substrate, the growth substrate has been detached. In particular, the semiconductor chip is a thin film chip.

According to at least one embodiment, the semiconductor chip comprises a carrier on which the semiconductor layer sequence is arranged. The carrier is different from the growth substrate. In particular, the carrier stabilizes the semiconductor layer sequence. The carrier may be electrically conductive. The carrier may be a silicon carrier.

According to at least one embodiment, the active layer is arranged between the carrier and the semiconductor structures.

According to at least one embodiment, the semiconductor structures each taper along a longitudinal axis of the semiconductor structure. For example, the semiconductor structures all taper along the same direction. For example, all of the semiconductor structures taper in a direction toward or all of them taper in a direction away from the active layer.

According to at least one embodiment, the semiconductor chip comprises a plurality of individually and independently controllable pixels. A controllable pixel emits or absorbs electromagnetic radiation. The semiconductor chip is then a pixelated semiconductor chip.

According to at least one embodiment, different semiconductor structures are assigned to different pixels. For example, two semiconductor structures formed as conversion elements, each of which converts the primary radiation of the active layer into different secondary radiation, respectively, are assigned to a pixel.

According to at least one embodiment, the active layer comprises a plurality of elevations, wherein a semiconductor structure is associated with each elevation. The elevations are, in particular, bulges or protuberances of the active layer that extend perpendicular to a main extension plane of the active layer. The elevations in the active layer may be caused, for example, by the growth of the semiconductor layer sequence on the semiconductor structures. For example, the elevations are formed by so-called V-pits. The V-pits can then each be assigned to a semiconductor structure. The elevations in the active layer can increase the luminance.

According to at least one embodiment, the semiconductor structures are embedded in a mirror layer of the semiconductor layer sequence. The mirror layer is in particular a Bragg mirror consisting of several semiconductor layers. The mirror layer may be epitaxially grown. For example, the mirror layer comprises a layer of n-doped AlInN and a layer of GaN. The mirror layer is a mirror for the primary radiation emitted by the active layer. Individual layers of the mirror layer fulfill, for example, the λ/4 requirement with respect to the primary radiation. Thus, the primary radiation can advantageously be made to stay longer in the mirror layer, which in turn increases the conversion probability by the conversion elements.

According to at least one embodiment, at least some semiconductor structures are arranged laterally adjacent to the active layer. In particular, these semiconductor structures are arranged in the same plane as the active layer. The semiconductor structures laterally next to the active layer serve in particular for the conversion of the laterally emitted primary radiation.

The active layer of the semiconductor layer sequence is structured, for example, into a plurality of pixels, wherein semiconductor structures are arranged in a common plane with the active layer in the region between two pixels.

Further semiconductor structures may be arranged above or below the active layer in a different plane than the active layer.

Furthermore, a method for producing an optoelectronic semiconductor chip is specified. The method is particularly suitable for producing a semiconductor chip as just described. All features disclosed in relation with the optoelectronic semiconductor chip are therefore also disclosed for the method and vice versa.

According to at least one embodiment, the process for producing an optoelectronic semiconductor chip comprises a step A) in which a growth substrate with a growth side is provided. In a step B), semiconductor structures each having an active region are grown on the growth side, in particular epitaxially grown. In a step C), a semiconductor layer sequence is grown on the growth side, in particular epitaxially grown. Here, each semiconductor structure is a nanorod or a microrod. The active regions of the semiconductor structures are each configured for emission and/or absorption of electromagnetic radiation. The active regions of different semiconductor structures are not connected. The semiconductor structures are embedded in the semiconductor layer sequence in the process.

Steps B) and C) are carried out alternately. For example, first a part of the semiconductor layer sequence is grown, then the semiconductor structures are grown, and thereupon another part of the semiconductor layer sequence is grown.

According to at least one embodiment, the semiconductor structures are overgrown with the semiconductor layer sequence. That is, the semiconductor layer sequence is grown on the semiconductor structures, wherein the semiconductor structures cause the semiconductor layer sequence to grow with a lower defect density. For example, the semiconductor structures cause the semiconductor layer sequence to grow together laterally (ELOG).

### BRIEF DESCRIPTION OF THE DRAWINGS

In the following, an optoelectronic semiconductor chip described herein and a method for producing an optoelectronic semiconductor chip described herein are explained in more detail with reference to drawings based on non-limiting embodiments. Identical reference signs thereby specify identical elements in the individual figures. However, no references to scale are shown; rather, individual elements may be shown exaggeratedly large for better understanding.

FIGS. 1A, 1B, 1C, 1E, 3A, 3B, 5A, 5B, 9 exemplary embodiments of the optoelectronic semiconductor chip in various views,

FIGS. 2A to 2I, 4A to 4F, 6A to 6E positions in various exemplary embodiments of the method for producing an optoelectronic semiconductor chip,

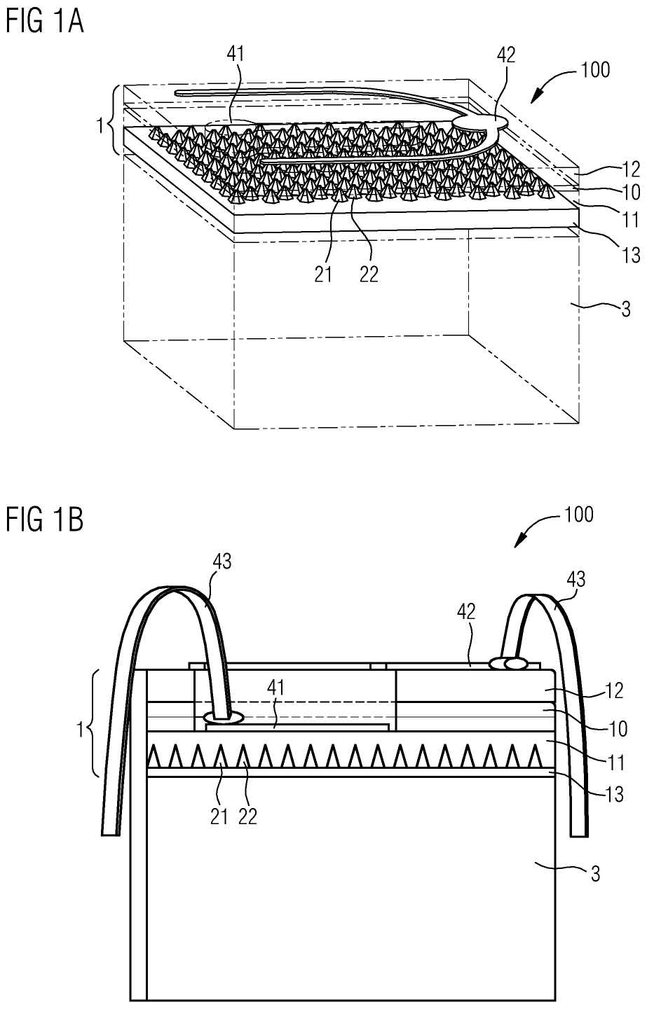

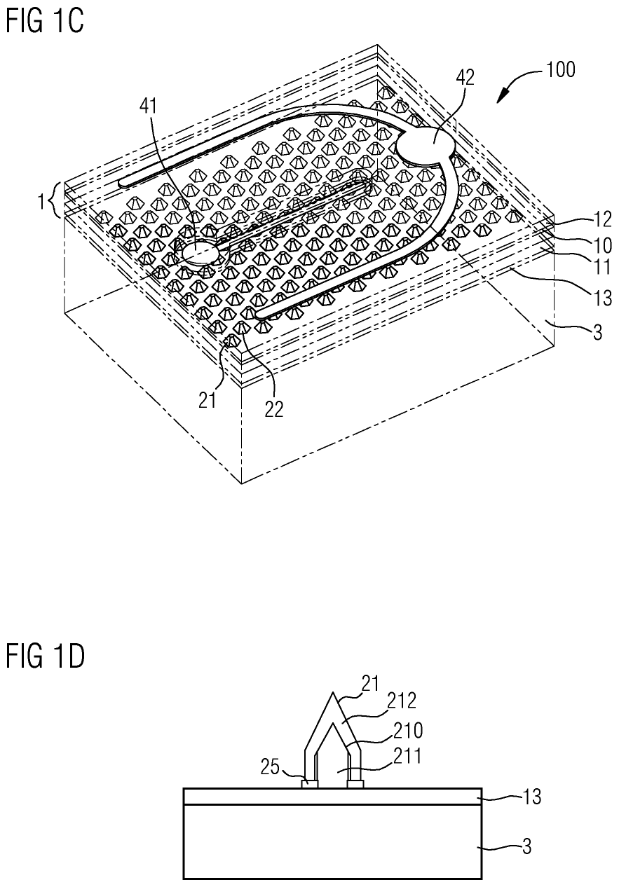

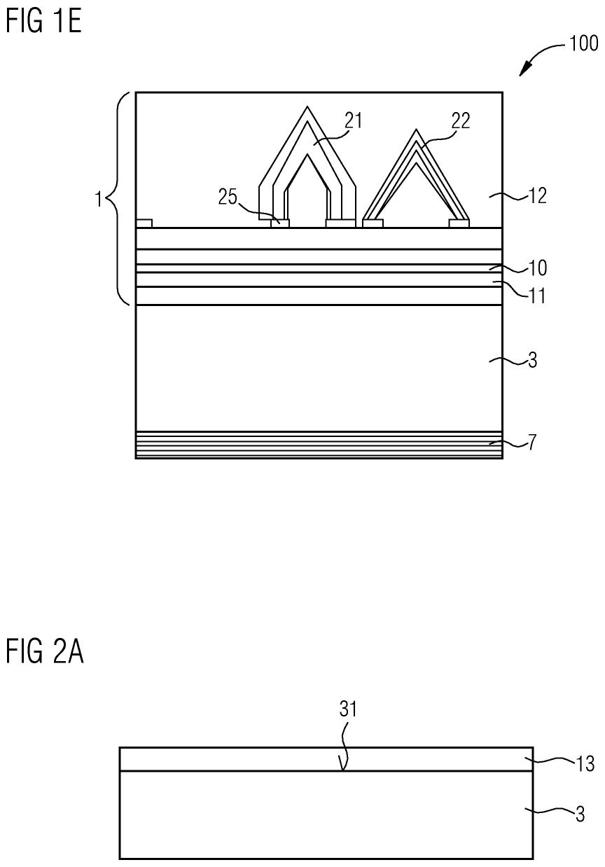

FIGS. 1D and 7 exemplary embodiments of semiconductor structures in detailed views,

FIGS. 8A to 8D positions in another exemplary embodiment of the method for producing an optoelectronic semiconductor chip, and an exemplary embodiment of an optoelectronic semiconductor chip.

### DETAILED DESCRIPTION

In FIGS. 1A to 1C, a first exemplary embodiment of the optoelectronic semiconductor chip 100 is shown in perspective views and side views. The semiconductor chip 100 includes a growth substrate 3, for example, a sapphire substrate. An auxiliary layer 13 is grown on the growth substrate 3. The auxiliary layer 13 is a semiconductor layer and is based on GaN, for example. Semiconductor structures 21, 22 in the form of nanorods or microrods are grown on the auxiliary layer 13. The semiconductor structures 21, 22 are conversion elements. First semiconductor structures 21 differ from second semiconductor structures 22, for example, in terms of conversion characteristics. The semiconductor structures 21, 22 are based on a nitride compound semiconductor material, for example.

The semiconductor structures 21, 22 are overgrown with a semiconductor layer sequence 1 based, for example, on AlInGaN. The semiconductor layer sequence 1 includes a first semiconductor layer 11. The first semiconductor layer 11 is, for example, n-doped. Downstream of the first semiconductor layer 11 is an active layer 10 in the form of a multi quantum well, MQW. In turn, a second semiconductor layer 12, which is p-doped, for example, is arranged downstream of the active layer 10.

Further shown in FIGS. 1A to 1C is a first contact element 41 for contacting the first semiconductor layer 11 and a second contact element 42 for contacting the second semiconductor layer 12. Both contact elements 41, 42 are arranged on a side of the semiconductor layer sequence 1 facing away from the growth substrate 3. The first contact element 41 is arranged in a recess of the semiconductor layer sequence 1 in which the first semiconductor layer 11 is exposed. The contact elements 41, 42 can be contacted with contact wires 43 from a side opposite to the growth substrate 3. The semiconductor chip 100 of FIGS. 1A to 1C is in particular a so-called sapphire chip.

In FIG. 1D, a detailed view of a first semiconductor structure 21 is shown. It can be seen that the first semiconductor structure 21 comprises a first semiconductor section 211 in the form of a core. The first semiconductor section 211 is encased with an active region 210. The active region 210 is for absorbing and/or emitting electromagnetic radiation. The active region 210 is encased by a second semiconductor section 212 in the form of a layer. Also shown in FIG. 1 are the remnants of a mask 25 used to grow the first semiconductor structures 21.

In FIG. 1E, a second exemplary embodiment of the optoelectronic semiconductor chip 100 is shown. Again, this is a sapphire chip. In contrast to FIGS. 1A to 1C, the semiconductor structures 21, 22 formed as conversion elements are now embedded in the semiconductor layer sequence 1 on a side of the active layer 10 facing away from the growth substrate 3. A mirror 7, for example a Bragg mirror, is arranged on a side of the growth substrate 3 facing away from the semiconductor layer sequence 1. Such a mirror 7 may also be provided in the exemplary embodiment of FIGS. 1A to 1C.

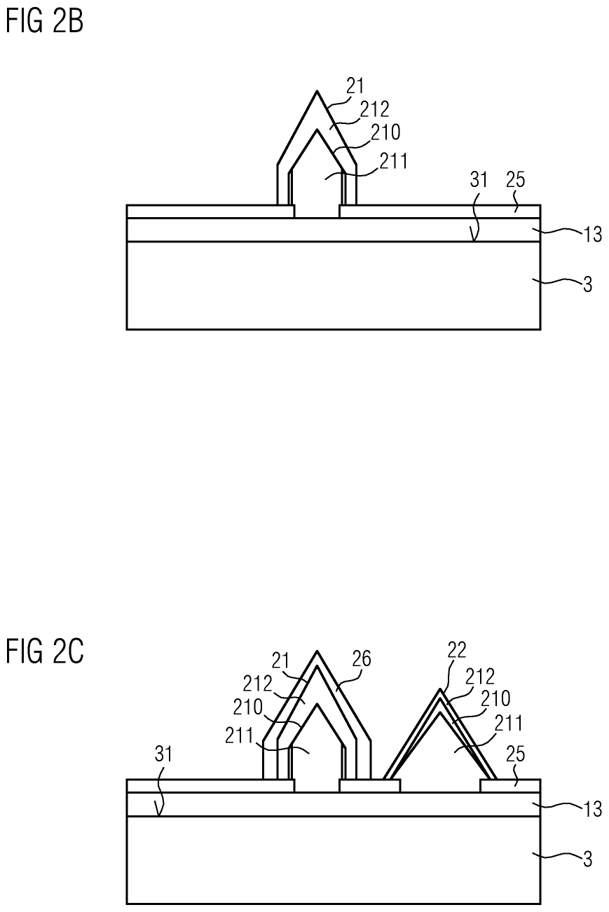

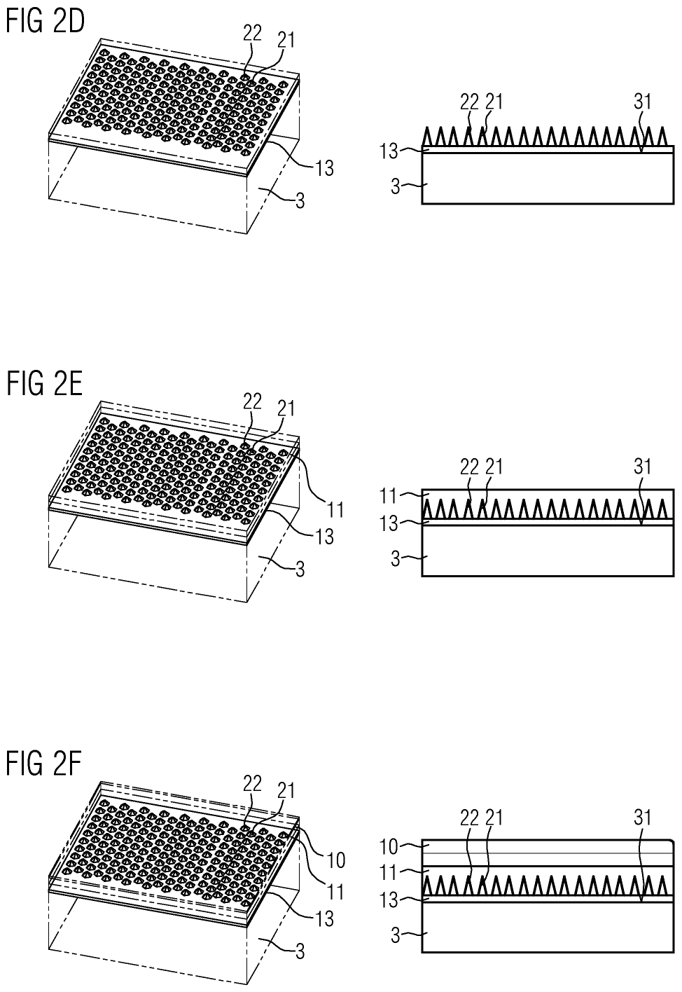

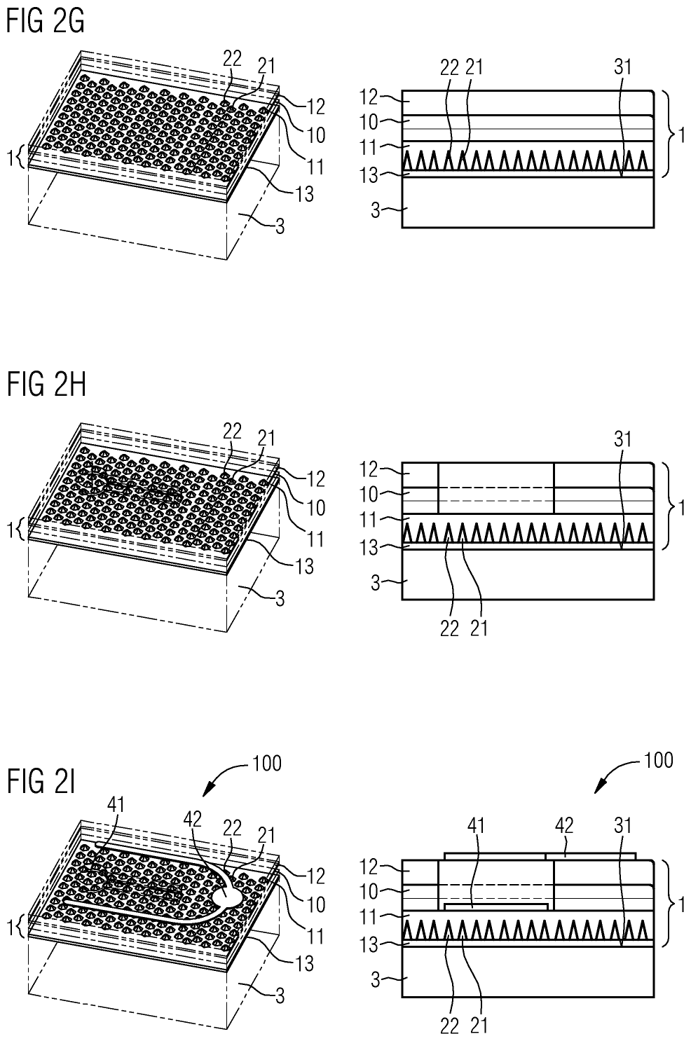

In the FIGS. 2A to 2I, various positions in a first exemplary embodiment of the method for producing the optoelectronic semiconductor chip of FIGS. 1A to 1C are shown.

In FIG. 2A, a growth substrate 3 with an auxiliary layer 13 is first provided. The auxiliary layer 13 is a semiconductor layer and is epitaxially grown on a growth side 31 of the growth substrate 3.

In FIG. 2B, a first semiconductor structure 21 in the form of a nanorod or microrod is grown on the growth side 31 of the growth substrate 3. For this purpose, a mask 25 was first applied to the growth side 31. The mask 25 may be formed, for example, with an electrically insulating material, for example, with a photoresist material and/or with a silicon oxide and/or with a silicon nitride. The mask 25 was then patterned by bringing in holes in the mask 25. The size of the holes in the mask 25 thereby defines the diameter of the semiconductor structures that are later formed. The first semiconductor structures 21 were then grown within the holes. These are, for example, green conversion elements.

In FIG. 2C the mask 25 is again structured with holes. Within the additional holes, second semiconductor structures 22 have again been grown in the form of nanorods or microrods. For the second semiconductor structures 22, for example, the diameters are chosen differently than for the first semiconductor structures 21. For example, these are red conversion elements. The first semiconductor structures 21 are coated with a passivation 26, for example SiO₂ or SiN. Other than shown in FIGS. 2B and 2C, the first semiconductor structures 21 and the second semiconductor structures 22 can also be grown simultaneously.

In the FIG. 2D the position of FIG. 2C is shown again in perspective view and cross-sectional view.

In the FIGS. 2E to 2G, it is shown how the semiconductor structures 21, 22 are first overgrown with a first semiconductor layer 11, then with an active layer 10 and then with a second semiconductor layer 12, so that a semiconductor layer sequence 1 is formed in which the semiconductor structures 21, 22 are embedded. The first semiconductor layer 11 may, for example, comprise or consist of a mirror layer, in particular a Bragg mirror.

In FIGS. 2H and 2I, it is shown how the semiconductor layers 11, 12 are subsequently contacted with contact elements 41, 42.

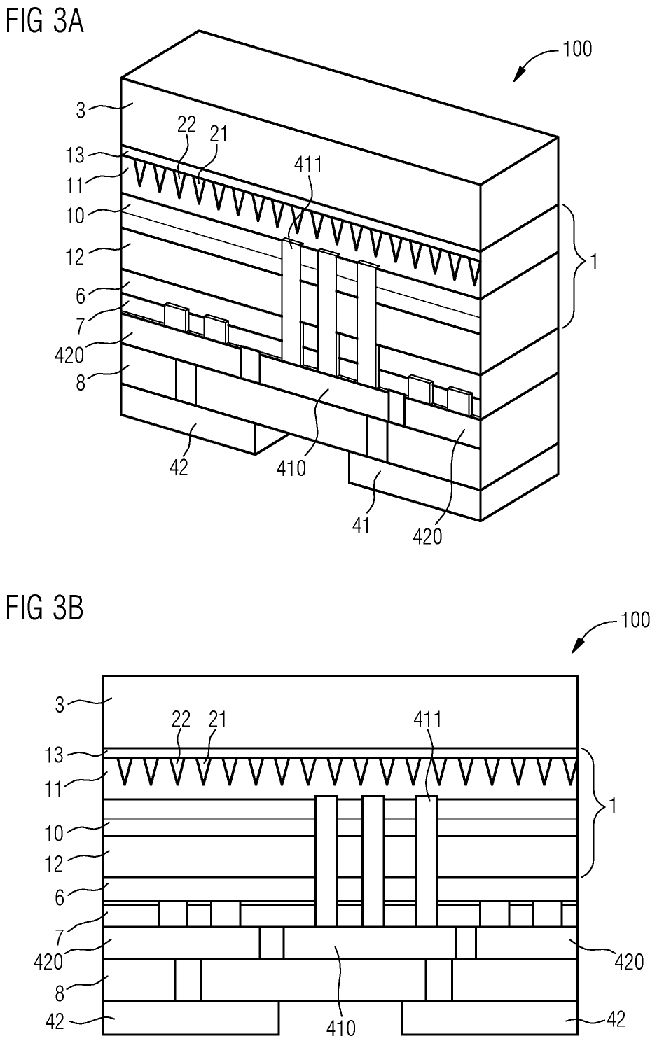

In the FIGS. 3A and 3B, exemplary embodiment of the optoelectronic semiconductor chip 100 are shown. This semiconductor chip 100 is a so-called flip chip. The contact elements 41, 42 for contacting the semiconductor layer sequence 1 are arranged on a side of the semiconductor layer sequence 1 facing away from the growth substrate 3. A contact layer 6 for contacting the second semiconductor layer 12 and a mirror 7 are arranged between the semiconductor layer sequence 1 and the contact elements 41, 42. The contact layer 6 is electrically conductively connected to a second electrode 420. The first semiconductor layer 11 is connected to a first electrode 410 by vias 411 extending through the second semiconductor layer 12 and the active layer 10. Both electrodes 410, 420 are arranged on the same side of the semiconductor layer sequence 1. An insulating layer 8 is arranged on the electrodes 410, 420. The electrodes 410, 420 are electrically conductively connected to the contact elements 41, 42 through the insulation layer 8.

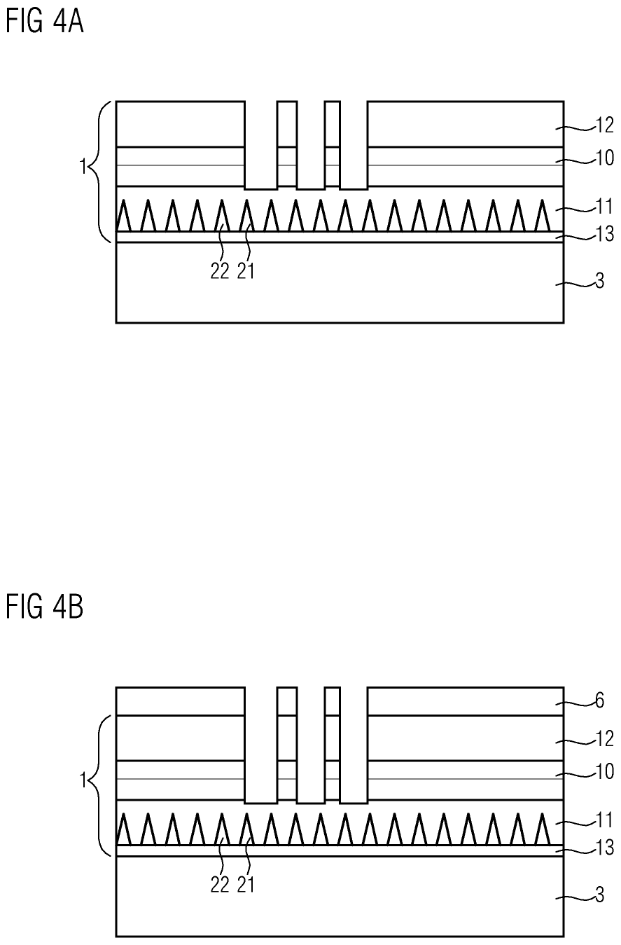

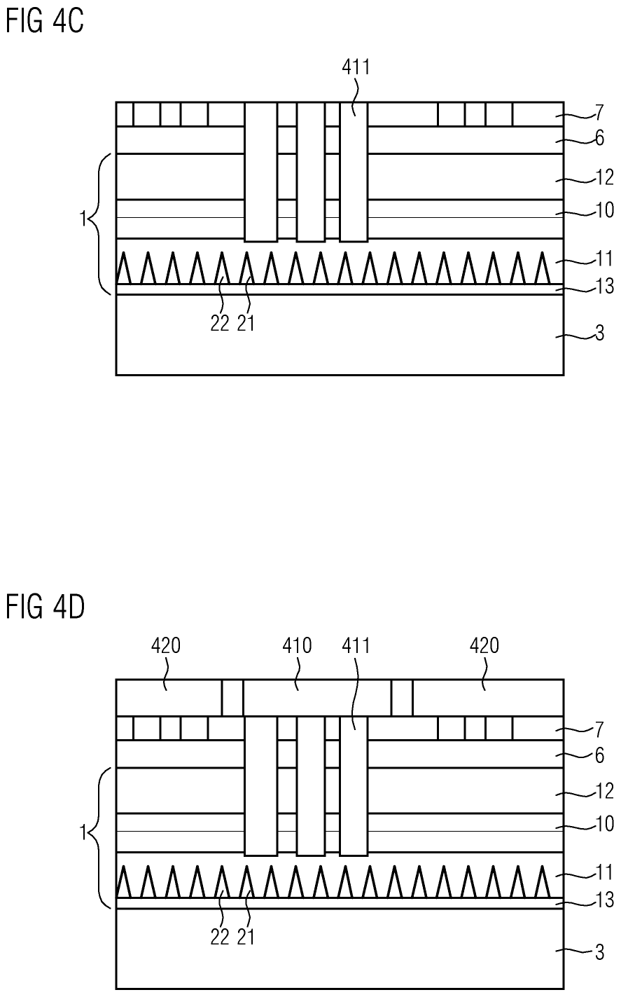

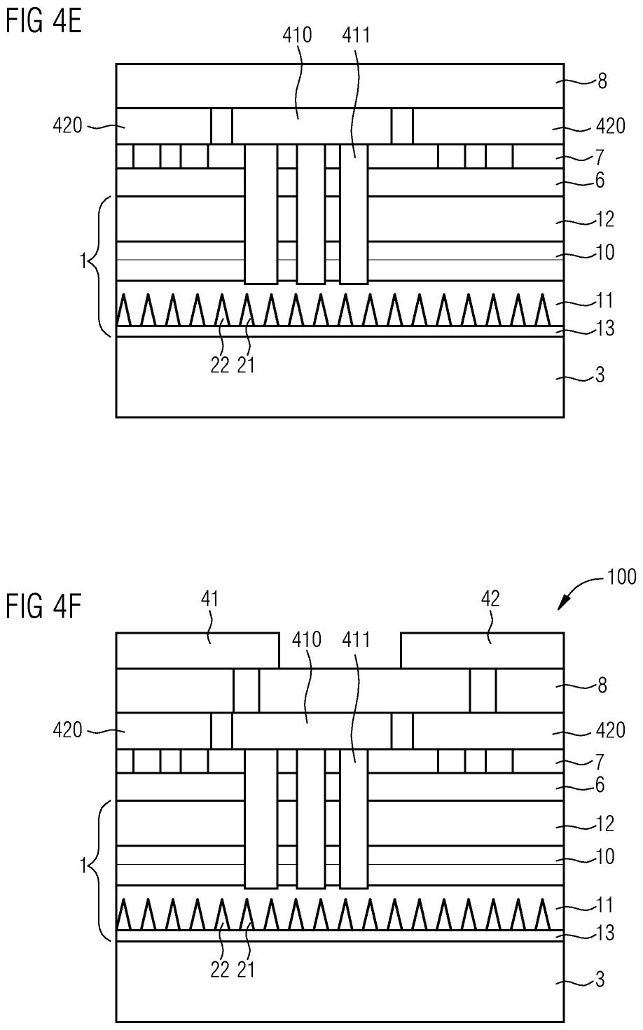

In FIGS. 4A to 4F, various positions of an exemplary embodiment for producing the semiconductor chip 100 of FIGS. 3A and 3B are shown. First, for example, the method as explained in relation with FIGS. 2A to 2G is carried out. The position shown in the FIG. 4A follows the position shown in the FIG. 2G.

In the FIG. 4A, openings are brought into the semiconductor layer sequence 1 from a side of the semiconductor layer sequence 1 facing away from the growth substrate 3, which extend through the second semiconductor layer 12 and the active layer 10 into the first semiconductor layer 11 and lead into the first semiconductor layer 11. Subsequently, a contact layer 6, for example made of silver, (FIG. 4B) and a mirror 7, for example made of metal, (FIG. 4C) are deposited on the second semiconductor layer 12. The openings are filled with an electrically conductive material, such as a metal (FIG. 4C). This creates vias 411 for contacting the first semiconductor layer 11. Electrodes 410, 420 are applied to the mirror 7 (FIG. 4D). The first electrode 410 is electrically conductively connected to the vias 411. The second electrode 420 is electrically conductively connected to the contact layer 6 via holes in the mirror 7. In FIG. 4E, an insulation layer 8 is applied to the electrodes 410, 420. The insulation layer 8 comprises, for example, silicon oxide or silicon nitride. In FIG. 4F, contact elements 41, 42 are then applied to a side of the insulation layer 8 facing away from the growth substrate 3.

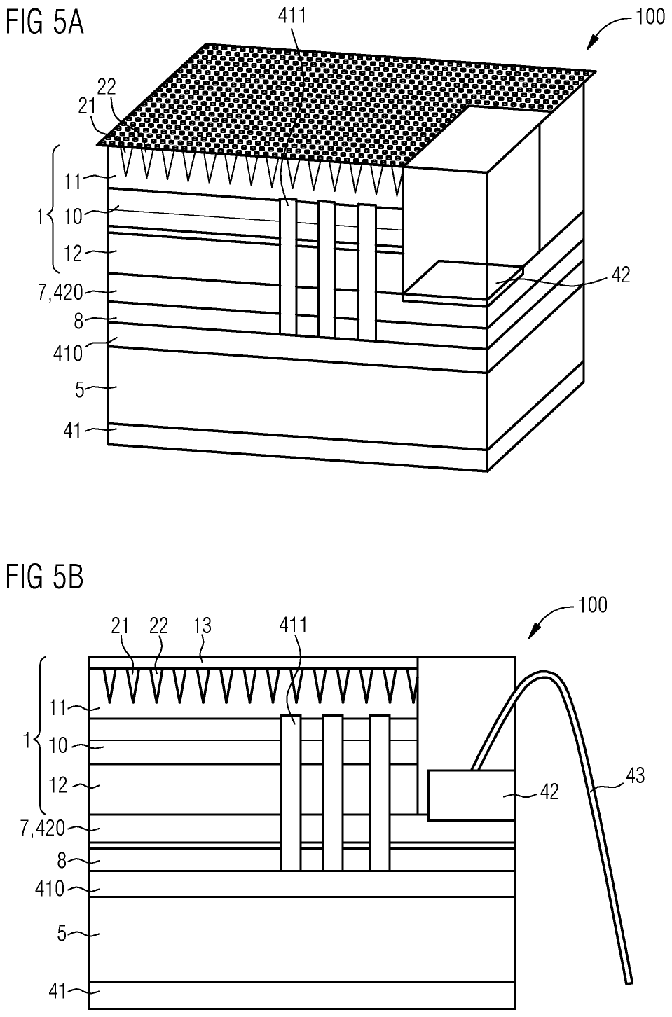

In the FIGS. 5A and 5B, a third embodiment of the optoelectronic semiconductor chip 100 is shown. Unlike in the previous exemplary embodiments, the growth substrate is now detached. For this purpose, a carrier 5, for example a silicon carrier, is additionally applied to a side of the second semiconductor layer 12 facing away from the active layer 10. A mirror 7, which also serves as a second electrode 420 for contacting the second semiconductor layer 12, is also provided between the second semiconductor layer 12 and the carrier 5. A first electrode 410 is applied to a side of the second electrode 420 facing away from the semiconductor layer sequence 1. The two electrodes 410, 420 are separated from each other by an insulation layer 8 and electrically insulated. The first electrode 410 is electrically conductively connected to the first semiconductor layer 11 by vias 411 which extend through the insulation layer 8, the second electrode 24, the second semiconductor layer 12 and the active layer 10 into the first semiconductor layer 11. The carrier 5 is applied to the first electrode 410.

A first contact element 41 is applied to a side of the carrier 5 facing away from the semiconductor layer sequence 1. In this case, the carrier 5 is electrically conductive.

A recess is also brought into the semiconductor layer sequence 1, which extends from a side of the semiconductor layer sequence 1 facing away from the carrier 5 to the second electrode 420. A second contact element 42 is provided in the recess for electrically contacting the second electrode 420. The second contact element 42 can be electrically contacted with a contact wire 43 from a side of the semiconductor layer sequence 1 facing away from the carrier 5 (FIG. 5B).

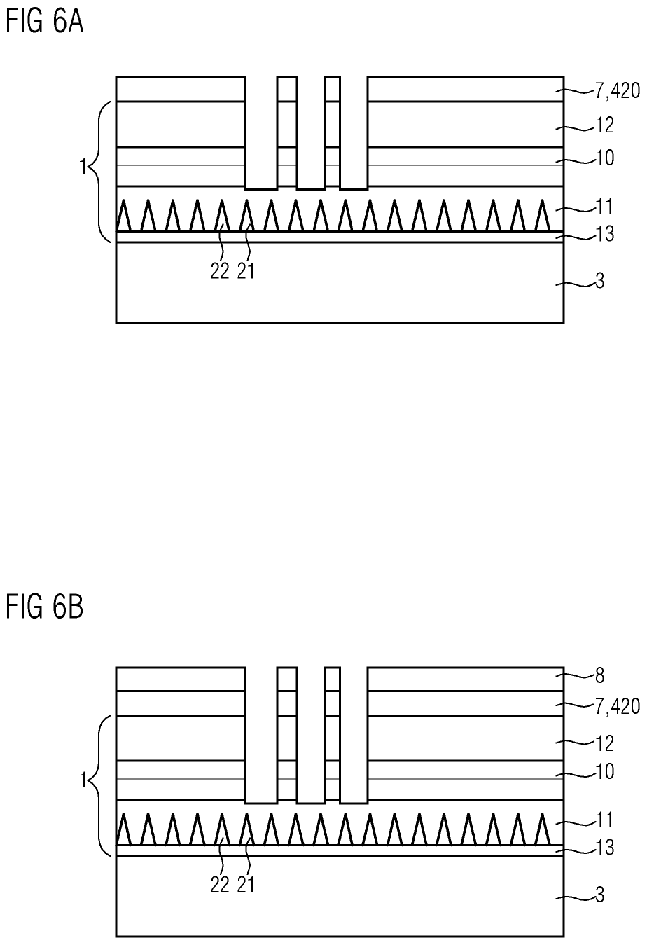

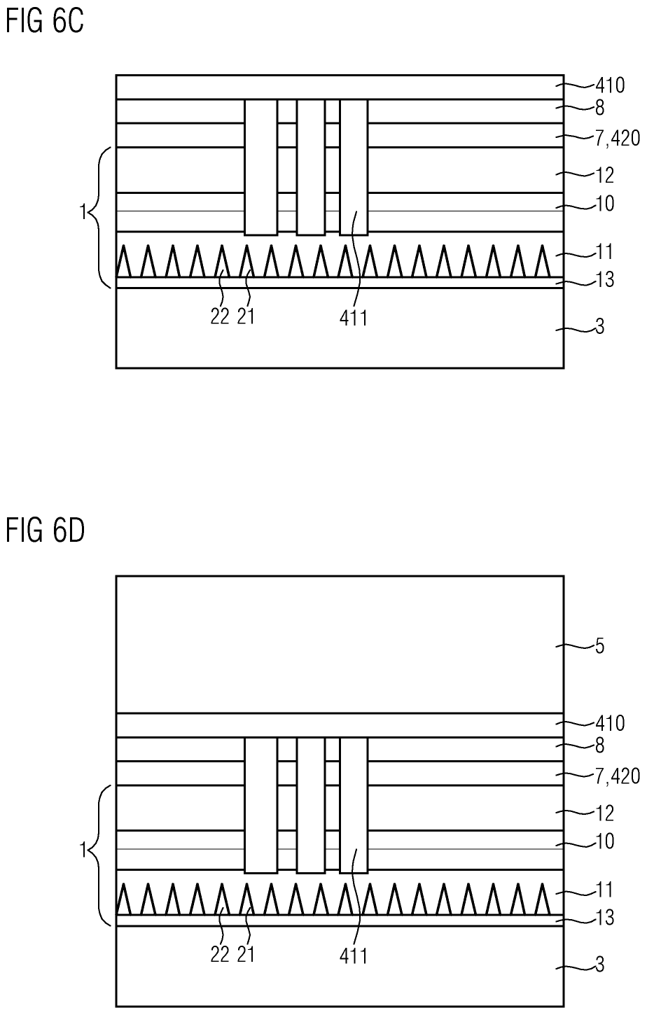

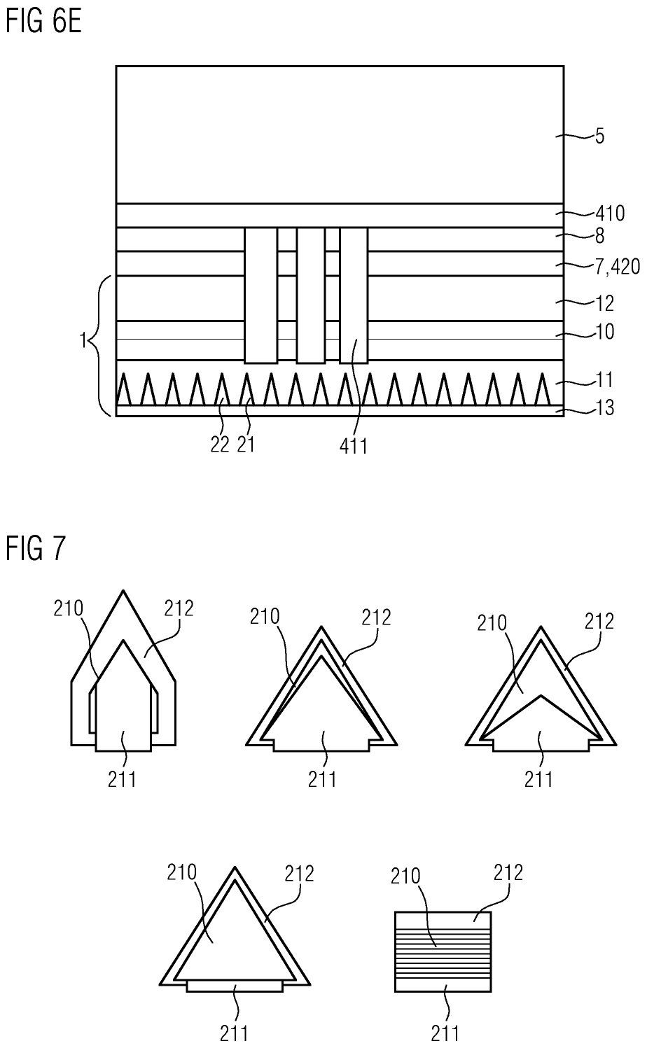

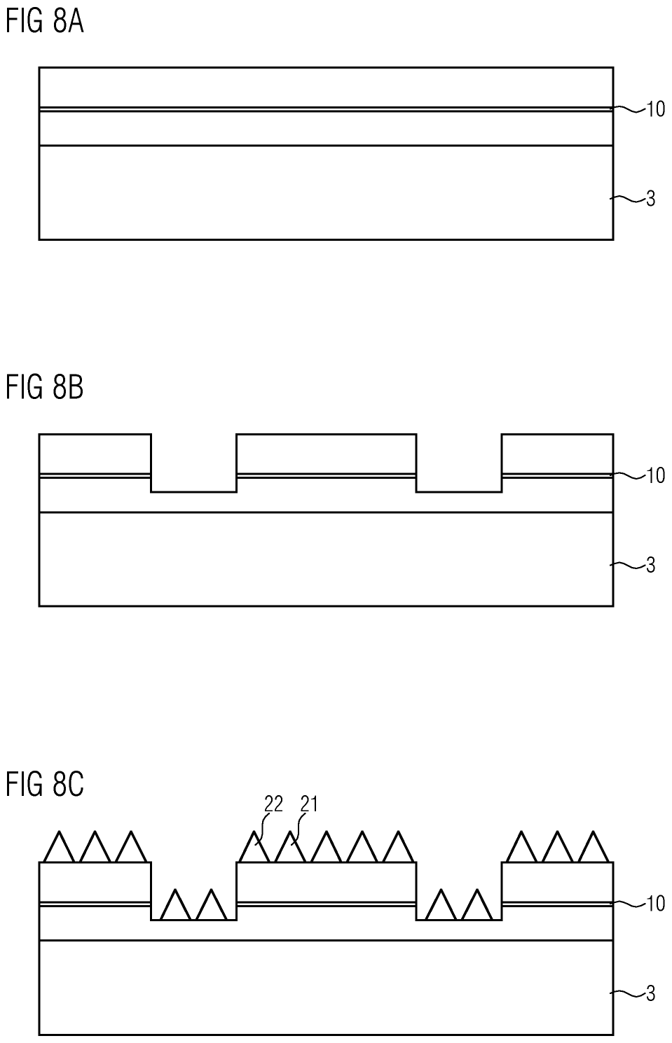

In the FIGS. 6A to 6B, various positions in an exemplary embodiment for producing the optoelectronic semiconductor chip according to FIGS. 5A and 5B are shown. First, for example, the method according to steps 2A to 2G was again carried out. The position of the FIG. 6A follows the position of the FIG. 2G.

In the FIG. 6A, openings are first brought into the semiconductor layer sequence 1 from a side facing away from the growth substrate 3. Also, a mirror 7, which also forms a second electrode 420, is provided on the second semiconductor layer 12. An insulating layer 8 is applied to the mirror 7 (FIG. 6B). A first electrode 410 is applied to the insulating layer 8 (FIG. 6C). Furthermore, the openings are filled with an electrically conductive material which is electrically conductively connected to the first electrode 410. As a result, vias 411 are formed in the semiconductor layer sequence 1. In FIG. 6D, a carrier 5, which is electrically conductively connected to the first electrode 410, is applied to the first electrode 410. The growth substrate 3 is then removed (FIG. 6E).

In the FIG. 7, various exemplary embodiments of the semiconductor structures are shown. The semiconductor structures may be core-shell rods that are, for example, cylindrical, pyramidal, or obelisk-shaped. The active regions 210 of the semiconductor structures may each be in the form of a multi quantum well.

FIG. 8A shows a first position in a further exemplary embodiment of the method for producing an optoelectronic semiconductor chip. A first part of a semiconductor layer sequence including an active layer 10 is grown on a growth substrate 3.

In FIG. 8B, a second position of the method is shown, in which the semiconductor layer sequence is patterned together with the active layer 10. In this case, the active layer 10 is removed in some regions. This is achieved, for example, by an etching process using an etching mask.

In the third position of FIG. 8C, semiconductor structures 21, 22 in the form of nanorods or microrods are grown on the rest of the semiconductor layer sequence. The semiconductor structures 21, 22 are conversion elements for converting the primary radiation emitted from the active layer 10. The semiconductor structures 21, 22 are grown both in the regions where the active 10 has been removed and in the remaining regions. In the regions where the active layer 10 has been removed, the semiconductor structures 21, 22 are located at the same level as the active layer 10 and, in particular, are located in a plane defined by the active layer 10.

In the FIG. 8D, a fourth position of the method, in which the semiconductor structures 21, 22 are overgrown with further semiconductor material and the semiconductor layer sequence 1 is completed, is shown. FIG. 8D simultaneously shows an exemplary embodiment of a finished optoelectronic semiconductor chip 100.

The semiconductor chip 100 of FIG. 8D comprises a segmented active layer 10. Each segment of the active layer 10 represents, for example, a pixel. These are, for example, individually and independently controllable. The primary radiation emitted by the segments of the active layer 10 is converted by semiconductor structures 21, 22 arranged above the segments. The semiconductor structures 21, 22 laterally adjacent to the segments of the active layer 10 convert the laterally emitted primary radiation.

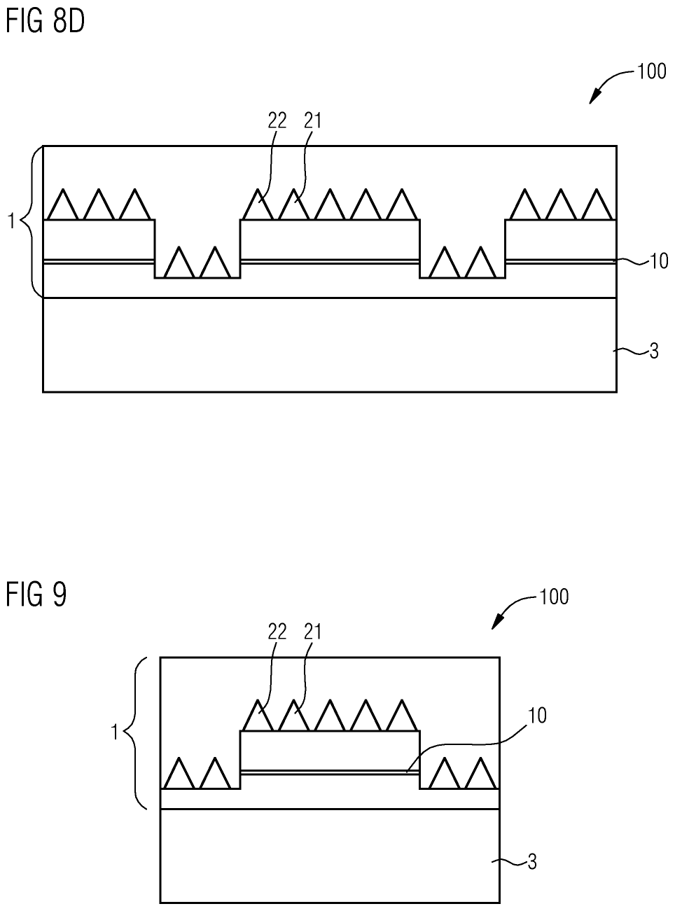

In the FIG. 9, another exemplary embodiment of an optoelectronic semiconductor chip 100 is shown. The semiconductor chip 100 comprises only a single, continuous and uninterrupted active layer 10, but this does not extend to the lateral boundary of the semiconductor layer sequence 1, but is laterally surrounded by semiconductor structures 21, 22 which convert laterally emitted primary radiation. Above the active layer 10, on a side of the active layer 10 facing away from the growth substrate 3, further semiconductor structures 21, 22 are provided for converting the emitted primary radiation.

The invention is not limited to the exemplary embodiments by the description thereof. Rather, the invention encompasses any new feature as well as any combination of features, which in particular includes any combination of features in the patent claims, even if these features or this combination itself are not explicitly specified in the patent claims or exemplary embodiments.

### LIST OF REFERENCE SIGNS

1 semiconductor layer sequence

3 growth substrate

6 contact layer

7 mirror

8 insulation layer

10 active layer

11 first semiconductor layer

12 second semiconductor layer

13 auxiliary layer

21 first conversion element

22 second conversion element

25 mask

26 passivation

31 growth side

41 first contact element

42 second contact element

43 contact wire

100 optoelectronic semiconductor chip

210 active region

211 semiconductor layer

212 semiconductor layer

410 first electrode

411 via

420 second electrode

1. An optoelectronic semiconductor chip comprising:
a semiconductor layer sequence; and
a plurality of semiconductor structures having a plurality of active regions; wherein:
the plurality of active regions are configured for the emission and/or absorption of electromagnetic radiation;
the plurality of active regions are not connected to each other; and
the semiconductor structures are formed as nanorods, microrods, or combinations thereof;
the semiconductor structures are embedded in the semiconductor layer sequence.

2. The optoelectronic semiconductor chip according to claim 1, wherein:
the semiconductor structures are conversion elements;
the semiconductor layer sequence comprises an active layer configured to generate or absorb a primary radiation;
the conversion elements are configured to convert the primary radiation into a secondary radiation or to convert a secondary radiation into the primary radiation.

3. The optoelectronic semiconductor chip according to claim 1,
wherein the semiconductor structures are epitaxially overgrown with the semiconductor layer sequence.

4. The optoelectronic semiconductor chip according to claim 2,
wherein the semiconductor structures are arranged between the active layer and a growth substrate of the semiconductor layer sequence.

5. The optoelectronic semiconductor chip according to claim 2, wherein:
the semiconductor chip is free of a growth substrate of the semiconductor layer sequence;
the semiconductor chip comprises a carrier on which the semiconductor layer sequence is arranged;
the active layer is arranged between the carrier and the semiconductor structures.

6. The optoelectronic semiconductor chip according to claim 1,
wherein the semiconductor structures each narrow along a longitudinal axis of the semiconductor structure.

7. The optoelectronic semiconductor chip according to claim 1, wherein
the semiconductor chip comprises a plurality of individually and independently controllable pixels; and
different semiconductor structures are assigned to different pixels.

8. The optoelectronic semiconductor chip according to claim 2,
wherein the active layer comprises a plurality of elevations and each elevation is associated with a semiconductor structure.

9. A method of manufacturing an optoelectronic semiconductor chip, wherein the method comprises:
providing a growth substrate having a growth side;
growing semiconductor structures each having an active region on the growth side; and
growing a semiconductor layer sequence on the growth side;
wherein:
each semiconductor structure is a nanorod or a microrod;
the active regions are each configured to emit and/or absorb electromagnetic radiation;
the active regions are not connected to each other;
the semiconductor structures are embedded in the semiconductor layer sequence;
the semiconductor structures are conversion elements;
the semiconductor layer sequence comprises an active layer configured to generate or absorb a primary radiation;
the conversion elements are configured to convert the primary radiation into a secondary radiation; and
the active layer comprises a plurality of elevations and each elevation is associated with a semiconductor structure.

10. The method according to claim 9,
wherein the growing the semiconductor layer sequence on the growth side comprises overgrowing the semiconductor structures with the semiconductor layer sequence.

11. An optoelectronic semiconductor chip comprising:
a semiconductor layer sequence; and
a plurality of semiconductor structures each having an active region;
wherein:
the active regions are configured for the emission and/or absorption of electromagnetic radiation;
the active regions are not connected to each other;
the semiconductor structures are formed as nanorods, microrods, or combinations thereof;
the semiconductor structures are embedded in the semiconductor layer sequence;
the semiconductor structures are conversion elements;
the semiconductor layer sequence comprises an active layer configured to generate or absorb a primary radiation;
the conversion elements are configured to convert the primary radiation into a secondary radiation or to convert a secondary radiation into the primary radiation; and
the active layer comprises a plurality of elevations and each elevation is associated with a semiconductor structure.
